(19) United States
(12) Patent Application Publication
(10) Pub. No.: US 2009/0176020 A1
(43) Pub. Date: Jul. 9, 2009

(54) Apparatus and method for treating and impregnating porous structures

(76) Inventor: Gerard J. Vaerewyck, Tarentum, PA (US)

Correspondence Address: PAUL BOGDON, 2181 Battenkill Lane, Gibsonia, PA, 15044, US

(21) Appl. No.: 12/322,834

(22) Filed: Feb. 9, 2009

Related U.S. Application Data
(63) Continuation-in-part of application No. 10/465,224, filed on Jun. 20, 2003, now Pat. No. 7,141,118.
Application No. 10/465,224 is a division of application No. 11/499,094, filed on Aug. 4, 2006.
Application No. 11/499,094 is a continuation-in-part of application No. 12/003,504, filed on Dec. 26, 2007.

(51) Int. Cl. B05D 3/00; C23C 16/54

(52) U.S. Cl. 427/294; 118/50

(57) ABSTRACT

Apparatus and method for treating by injecting a fluid treatment material into the bodies of porous structures such as those formed from concrete, brick, stone, marble, and wood. The apparatus for use in the method includes an applicator head having an inner chamber and an outer chamber surrounding the inner chamber both of which chambers are connected with a vacuum source. The inner chamber is also connected with a source of pressurized liquid treatment material. The method is non-invasive in that the fluid treatment material impregnates the porous structure without the need to break open, destroy, repair, or replace any part of the structure, and includes the steps of engaging the structures with the applicator head, drawing a vacuum on at least the outer chamber to secure the applicator head to the structure, and supplying the pressurized liquid treatment material to the inner chamber to and onto the surface of the structure to impregnate the structure to be treated.

### RELATIONSHIP TO OTHER PATENT APPLICATIONS

This patent application is a Continuation-In-Part Application of U.S. patent application, Ser. No. 10/465,224, now U.S. Pat. No. 7,141,118 B2 and pending Divisional Application of U.S. patent application Ser. No. 11/499,094, in the name of GERARD J. VAEREWYCK, et al for APPARATUS AND METHOD FOR TREATING AND IMPREGNATING POROUS STRUCTURES, and pending Continuation-In-Part Application Ser. No. 12/003,504 in the name of GERARD J. VAEREWYCK for APPARATUS AND METHOD FOR TREATING AND IMPREGNATING POROUS STRUCTURES.

### BACKGROUND OF THE INVENTION

1. Field of Invention

This invention relates to apparatus and method for treating by injecting a fluid treatment material into the body of porous structures such as those formed from concrete, brick, stone, marble and wood including those structures with metal reinforcement members or other members embedded therein. The method of this invention is non-invasive in that fluid treatment material impregnates the porous structure without the need for breaking open, destroying, repairing, or replacing any parts of the structure.

2. Description of the Prior Art

Buildings, roads, bridges, tunnels, airport runways, marine supports, monuments, sculptures, art works, and various other man made outdoor structures that are formed of concrete, masonry, brick, stone, marble or wood all of which are porous in varying degrees. Many of these structures have metal, such as steel, reinforcement members or other members embedded therein. These outdoor structures are exposed to the environment including water and various hazards from atmospheric pollutants and conditions such as acid rain, salt, extremes of temperature and other airborne and water pollutants. Reinforcing steel members embedded in the porous structures increase deterioration created by the corrosion and oxidation of the steel following erosion of the surrounding material caused by the pollutants in the atmosphere and water. The pollutants, acid in character, penetrate and react with the salts present in the material resulting in slow and persistent erosion, cracking, crumbling, spaulling, and eventual failure of the exposed porous structures.

As carefully described in U.S. Pat. Nos. 5,413,808 and 5,565,032 and other U.S. patents issued in the name of Jay S. Wyner, and repeated herein, the heretofore methods of treating and preserving porous structures of the nature referred to above, have provided only short term and often times inadequate protection. Preservative materials applied by brush, spray, roll-on, and even pressure injection methods, achieves only shallow penetration by capillary action. A single coating of the preservative material proved insufficient with a second coating tending to clog the porous structure's breathing passages according to the National Bureau of Standards Report No. 1118. With the surfaces of the porous structures clogged, internal stresses and pressures develop within, created by the effect of thermal changes on the ever-present moisture in masonry. As a result, the trapped vapor pressure generated thereby breaks through and cracks, delaminates, and destroys the protective coating.

Other methods, invasive of the structure to be treated, have been used in attempts to preserve porous structures of concrete or masonry. The structure is opened, rusted reinforcing members are cleaned, the structure repainted, the reinforcing members replaced where needed, and the outer structure then repaired. In another invasive method, holes are drilled in the structures containing reinforcing steel members, a preservative material applied under manual or pump pressure, the holes refilled and the masonry repaired. One such invasive method is disclosed in U.S. Pat. No. 3,865,075 issued in the names of James H. Klein et al which requires drilling of holes of about 9 inches through the surface of a structure and inserting probes into the holes. The process of treating disclosed in Klein et al suggests injecting treatment material without indicating any injection pressure. The probes of Klein et al and the holes in which they are inserted are surrounded by a so-called impregnator plate with an undisclosed slight negative pressure or vacuum maintained within the confines of the plate. The holes formed in the structure would necessarily require repair after the probes are removed. No known success has been evidenced with the Klein et al process. Yet another invasive method used on roadbeds and such like structures involved cutting elongated slots or grooves, filling the slots or grooves with coating material. These preservation methods are slow, tedious, costly, and oftentimes somewhat ineffective.

As to wood preservation, paint, shellac, epoxies, or urethanes are applied to the surfaces resulting in protection which lasts a few seasons before the need arises to scrape and sand the old protective surface and repeat the coating applications. Damage often results to the original coating from the shallow penetration and sealing effect of applications made by brush, roll-on or spray. The cellular resin structure of wood tends to cause a chemical migration in the wood when thermal expansion stresses, such as hot and cold weather conditions, are imposed. During the warm weather times, the expansion stresses cause the coatings to expand as a result of the forces imposed by the wood's cellular resins. At colder weather conditions, the contraction stresses cause the coatings to crack and peel, allowing moisture, acid rain and pollutant intrusion to cause the coatings to lift off the structures when freeze-thaw cycles occur. Moisture and pollutant absorption into the wood fibers accelerates decay.

Various concrete structures are formed in marine or water environments such as piers, sea walls, tunnels, bridge supports, and various others. In order to treat such water surrounded structures, enclosures or dikes are formed around the structure, the surrounding water pumped out, and the treating processes followed. Certain of those processes described hereinabove have been used. Extreme care is required to insure separations of the water from the structure in following the time consuming method used for treating water bound structures. The presently used methods of preservation and treating porous structures are inadequate in providing deep impregnation of treating liquids into the structure. Additionally, the methods and treating apparatus cannot be used effectively on all structures. Typically, brushing, rolling, spraying, or pressure injecting treating liquid on vertical structures is seriously ineffective since those methods rely on gravity and capillary action to move the liquids into the structure. Although concentrated pressure injecting of treating liquids into a structure or substrate results in some degree of impregnating, the methods used are limited in that they are useable with structures such as construction lumber, utility poles, and certain portable concrete structures where the various structures are placed in a fixed tank and subjected to pressurized treating liquids. These pressure systems are not useable on outdoor structures of the kinds already mentioned. Apparatus for injecting preservative liquids into porous structures are limited to use on flat, horizontally oriented structures such as floors, roads, walkways, tunnel and bridge surfaces, runways, and such like. Spraying treatment material also results in the bouncing of the liquid as it hits the surface of the structure resulting in unnecessary waste of the treatment material. It has been found that spraying on outdoor structures does not result in deep penetration of the treatment material into the structures. Aside from not being useable on upright or vertical oriented structures, the known pressure injection apparatus is not useable under water or on ceilings.

The present invention overcomes the problems inherent in existing methods and apparatus for treating outdoor porous structures, by providing a method for treating and deep impregnation of such porous structures, by providing an apparatus and non-invasive method for treating and deep impregnation of such porous structures and which apparatus and method are useable on upright structures, ceilings, underwater as well as on standard horizontally oriented structures without invading or in any way breaking, opening, or drilling into its structure. The apparatus and method of this invention are also readily useable on structures of virtually any shape or form, such as on cylindrical, fluted, artistically formed, layered structures or statues and monuments, for example. The apparatus of this invention which applies the inventive method, is simple in construction and relatively inexpensive to produce while achieving the results of deep penetration and impregnation of fluid treatment material into porous structure of virtually any configurations and orientation including walls and ceilings in the atmosphere or under water.

### SUMMARY OF THE INVENTION

The present invention provides apparatus and method for non-invasive preservation and treatment of porous structures such as those formed from concrete, brick, stone, marble, and wood including those structures above and below ground and in water and those structures having embedded therein metal reinforcement members or other members. The apparatus and method of this invention effect the treatment and preservation of porous structures without the need for breaking open, destroying, repairing, or replacing any part of the structure. Additionally, the present invention, both the apparatus and method, is effectively useable on upright structures, ceilings, structures under water, monuments, sculptures, and other solid art works.

The non-invasive method of the present invention is for treating by injecting a fluid treatment material such as a liquid preservative into a porous structure such as those formed from masonry, concrete, brick, stone, marble, and wood including those structures having reinforcement members or other members embedded therein, whether those structures are situated in the atmosphere or under water. Typical of the structures treatable by the method of the invention would be sidewalks, airport runways, parking garages, building walls and ceilings, bridge decks, bridge piers, tunnels, roof decks, balconies, monuments, statues, sea walls, containment dikes, foundations and such like. The non-invasive method of this invention in its preferred form includes the steps of engaging in sealed relationship to a porous structure to be treated an applicator head of the present invention having defined therein at least one outer first chamber and at least one inner second chamber within the confines of the first chamber, the chambers sealed from each other, with the chambers communicating with the structure to be treated; drawing a vacuum on each of the chambers to secure the applicator head to the structure; withdrawing the vacuum from the inner second chamber; supplying a pressurized fluid treatment material such as a liquid preservative to the inner second chamber and the structure to be treated until the structure is impregnated with the preservative material to a desired depth and; while supplying the treatment material maintaining the drawing vacuum on the outer first chamber and continuing supplying the preservative material to the inner second chamber to keep the applicator head in sealed engagement with the structure. Securing the applicator head in place on the structure with the applicator head sealed from the surrounding environment permits the treating of any structure whether it is located in the atmosphere or under water, or whether it is upright, such as a vertical wall, a ceiling, or a typical horizontal structure, such as a runway, walkway, bridge deck, and such like. The pressurized treatment material is applied after vacuum is removed from the inner second chamber and is applied in a contained setting avoiding splattering or bouncing of the material from the surface of the structure, or its running down from upright structures. The removal of the vacuum and applying pressurized treatment material allows for deeper penetration of the treatment material into the porous structures. The containing and focusing of the pressurized preservative on the structure results in rapid, effective impregnation of the structure with virtually no waste of the material. Typical negative pressure or vacuum to be applied in the treating process would be between 25 and 27 mmHg with the pressure of the treating material being between 10 and 15 lbs/sq. in. Lower vacuum and higher treatment material pressure could also be applied in certain conditions of the structure to be treated.

The apparatus of the present invention for practicing the inventive method of treating by injecting a fluid treatment material into porous structures formed from masonry, concrete, brick, stone, marble, and wood, including those structures with reinforcement members embedded therein, comprises, in its preferred form, an applicator head of the present invention constructed to engage at least a surface section of a porous structure to be treated; the applicator head defining at least one second chamber having an outer peripheral border engageable with a surface portion of a structure to be treated, and at least one outer first chamber surrounding said second chamber and having a peripheral border engageable with the surface portion of a structure to be treated; vacuum producing means, such as a venturi pump, communicating with at least the outer first chamber for drawing a vacuum in the chamber when the applicator head is in engagement with the porous structure to be treated to positively secure the applicator head to the structure; first sealing means communicating with the peripheral border of the inner second chamber for effecting a seal between the inner second chamber and a porous structure to be treated and between the inner second chamber and the outer first chamber when the applicator head engages the structure to be treated; second sealing means communicating with the peripheral border of the outer first chamber for effecting a seal between the first chamber and the structure to be treated; fluid treatment material means, such as a contained vessel and a positive discharge pump, communicating with the inner second chamber for selectively applying pressurized treatment material to the porous structure to be treated; and control means for selectively controlling the functioning of the vacuum producing means and the liquid preservative material means. The applicator head, the first and second sealing means, the liquid preservative material means and the control means being constructed and arranged such that when the applicator head engages a porous structure to be treated and a vacuum is drawn on the outer first chamber the applicator head is positively secured to the structure and sealed from the surrounding environment, and fluids in and on the porous structure tend to be drawn therefrom and discharged from the applicator head, and when pressurized material is supplied to the inner second chamber the porous structure engaged by the applicator head is impregnated with preservative material. A portable carriage may be used to support the vacuum producing means, the fluid treatment means, the means being typically a venturi pump, and a storage vessel and pump, respectively, and the control means. The applicator head would communicate with the vacuum and liquid preservative means by suitable hoses or tubing. Since the applicator head is positively secured to the structure to be treated and its interior effectively sealed from the surrounding environment, be it the atmosphere or water, the apparatus is useable on ceiling structures, upright structures, such as vertical walls, on land or in bodies of water. The applicator head may be shaped to conform to differing shapes of porous structures to be treated. Also, a number of applicator heads may be used for treating different porous structures. Where wide structures, such as airport landing runways, roads, and the like, are to be treated ganged, interconnected, side-by-side applicator heads could be used. In a slab arrangement, such as an elevated deck or the like, to be treated, one applicator head would be arranged on the top of the slab and another on its undersurface.

The basic method of treating porous structures of the present invention is simple, easy to understand, easily controlled, and rapid in operation. The basic structure of the apparatus of this invention is simple in construction, comprised of few elements, relatively inexpensive to produce utilizing standard components, and uncomplicated and efficient in its use. This apparatus is modifiable in various ways, for example in the types of pumps, containment vessels, and control arrangement, as well as differing shapes and sizes of applicator heads.

The applicator head or hood of this invention would preferably comprise a top structure and side walls for forming an inner second chamber; an inner wall for defining an outer first chamber surrounding the second chamber; fluid treatment material means defining at least one opening into the inner second chamber for supplying pressurized fluid into the inner second chamber; vacuum drawing means defining at least one opening into the outer first chamber for drawing a vacuum in the first chamber; and the top structure, inner wall, fluid treatment means, and vacuum drawing means being constructed and arranged such that the applicator head will engage a porous structure to be treated. As a particular situation might require, the inner second chamber may be provided with a plurality of openings through which fluid treatment material would be discharged. The overall shape of the applicator head may conform to a particular shape of a structure to be treated, as, for example, a generally cylindered shape for treating a cylindrically shaped support.

Various other advantages, details, and modifications of the present invention will become apparent and indicated as the following descriptions of a certain preferred embodiment and certain present preferred method of practicing the invention proceed.

### BRIEF DESCRIPTION OF THE DRAWINGS

In the accompanying drawing we show a certain present preferred embodiment of our invention in which:

FIG. 1 is a perspective view of the apparatus for treating a porous structure of the present invention, with parts cut away to show details of construction;

FIG. 2 is a side elevational sectional view of the applicator head of the present invention in engagement with a structure to be treated and diagrammatic representation of various parts of the apparatus in their relationship to the applicator head;

FIG. 3 is a side elevational sectional view looking through line II-II of FIG. 1 of the applicator head of the present invention shown in its free state illustrating the seal members in their extended form;

FIG. 4 is an enlarged sectional and perspective view of a part of one of the seal members showing details of construction;

FIG. 5 is a perspective view of the applicator head of the present invention looking at its underside to show the detail for construction of the inner and outer chambers thereof and the seal members on the peripheral borders of the chamber;

FIG. 6 is a part diagrammatic and part schematic of the various parts and hydraulic circuitry, respectively, of the apparatus of the present invention;

FIG. 7 is a perspective view of the applicator head of the present invention similar to FIG. 5 showing multiple parts or openings in the inner chamber;

FIG. 8 is a perspective view of the top side of the applicator head of FIG. 7 showing the tubing connections to the openings in the inner chamber;

FIG. 9 is a diagrammatic and schematic representation of an applicator head of the present invention showing the inner chamber formed in four sections;

FIG. 10 is a diagrammatic and somewhat schematic representation of a multi-applicator head arrangement on a porous slab showing one applicator head on the upper surface of the slab and one on its underside; and

FIG. 11 is a perspective view of an applicator of the present invention of a semi-cylindrical shape for use on a cylindrical structure with a similar shaped complementary applicator head for together surrounding a cylindrical structure to be treated.

### DESCRIPTION OF A PREFERRED EMBODIMENT AND METHOD

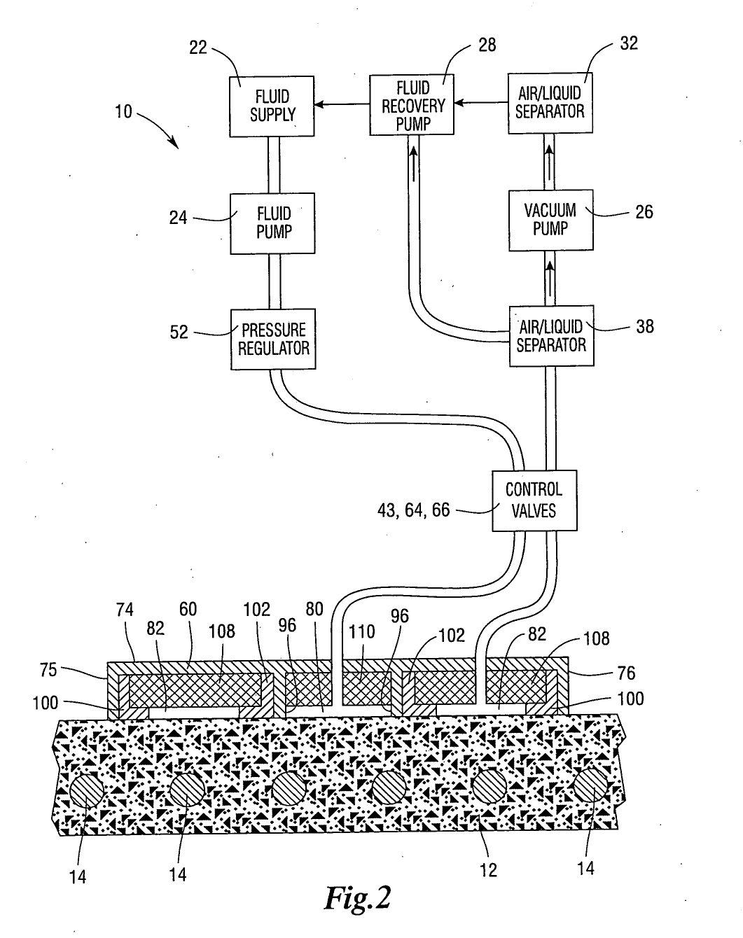

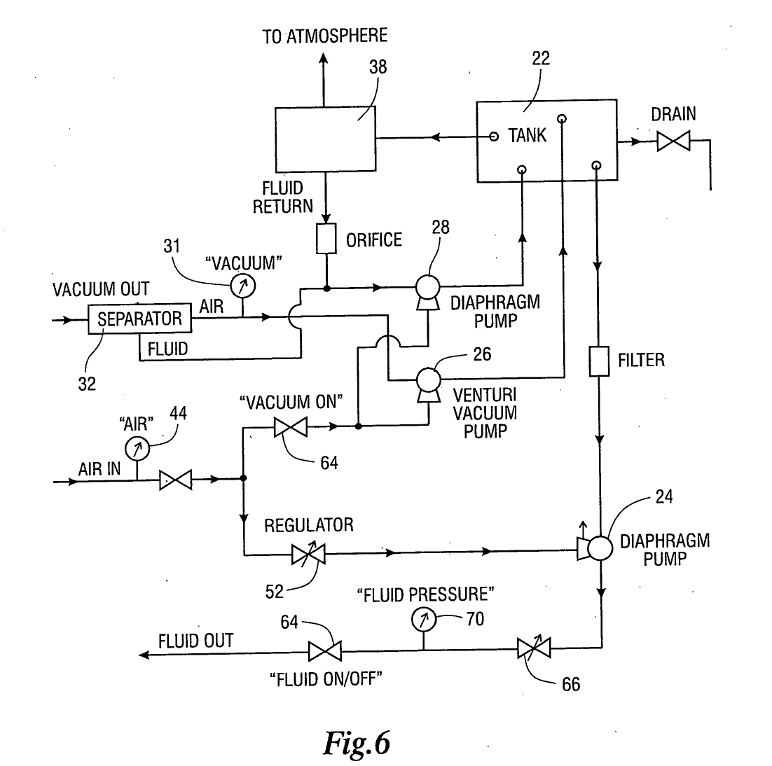

Referring now to the drawing there is shown an apparatus 10 for treating a porous structure formed from concrete, masonry, brick, stone, marble, or wood including those structures with reinforcement members or other members embedded therein. Typical of such porous structures are building parts, roads, bridges, airport runways, marine supports, monuments, sculptures, art works, and various other man made outdoor structures. The apparatus and method of the present invention are useable to treat structures in the atmosphere or under water, and structures which are upright, such as walls, and ceilings. FIG. 2 shows a section of a porous concrete structure 12 which could be typically a building floor, roadbed, walkway, or an airport runway, having embedded therein steel reinforcing rods 14. The apparatus 10 would be used for treating the porous structure 12, apparatus 10, as shown in the various figures, includes a portable frame or carriage 16 which may be moved from place to place by manually pushing or pulling, the carriage 16 mounted on wheels 18 and 20. Supported by the carriage 16 is a typically cylindrically shaped, close ended fluid supply storage tank 22 operatively connected by suitable tubing 23 to a standard liquid pump 24, typically any well known air operated diaphragm pump. Any suitable liquid preservative or treatment material would be stored in storage tank 22 which is also operatively connected by suitable tubing 25 to a vacuum pump 26, typically any well known operated venturi type vacuum pumps. Storage tank 22 is also operatively connected by suitable tubing 27 to a liquid recovery pump 28 which, as will be clearly understood as this description continues, serves to return to the storage tank 22 any unused treatment material from the surface of a structure to be treated. Liquid recovery pump 28 would be any well known air operated diaphragm pump. Vacuum pump 26 is connected by suitable tubing 30 to a vacuum gauge 31 and a liquid/air separator 32 which in turn is connected by tubing 33 to liquid recovery pump 28. The interconnection of the elements described above and to be described are shown schematically and diagrammatically in FIG. 6.

Storage tank 22 and liquid recovery pump 28 are connected by tubing 34 and 36 respectively to a liquid/air separator 38 which would separate any air from the tank 22 and/or from any unused treatment liquid from the structure treated. The liquid/air separator is vented to the atmosphere for discharging the separated air.

Inlet air from the atmosphere is directed through a compressor, not shown, to the vacuum pump 26 by suitable tubing 42, through a manually operated main air on/off valve 43, the air pressure being registered on an air inlet pressure gauge 44 connected with tubing 46. The inlet air entering the system through tubing 42 would typically be at about 120 psi.

Liquid pump 24 is operatively connected with compressed atmospheric air by suitable tubing 50 connected with tubing 42. Tubing 50 is connected to an air pressure regulator 52 which in turn is connected to the inlet of liquid pump 24.

Liquid recovery pump 28 is operatively connected with atmospheric air by suitable tubing 54 interconnected with tubing 50 which as described is connected with tubing 42 through which atmospheric air would flow.

An applicator head 60 is operatively connected with the liquid treatment material stored in storage tank 22 by suitable tubing 62 which is connected with an on/off valve 64 which in turn is connected with a liquid pressure regulator 66 connected in turn with the outlet of liquid pump 24 by suitable tubing 68. A fluid pressure gauge 70 for reading the outlet pressure of the liquid pump 24 communicates with tubing 68. Applicator head 60 is also operatively connected with the vacuum pump 26 through the liquid/air separator 32 by suitable tubing 72.

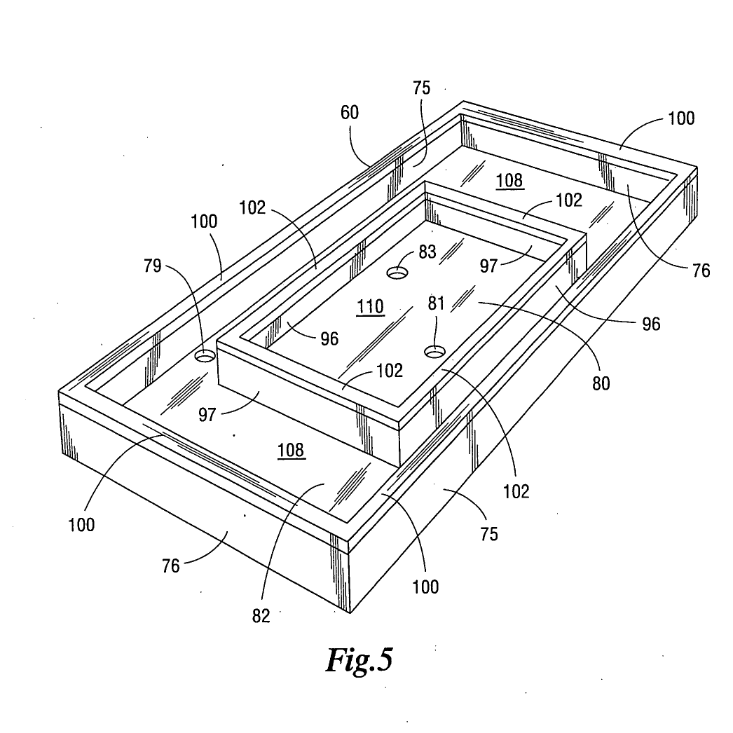

Applicator head 60 as shown in this embodiment of the invention is generally rectangular in shape having a flat upper section 74 and shallow longitudinal side walls 75 and lateral end walls 76. As shown in the bottom view of FIG. 5, there is defined within the confines of applicator head 60 inner compartment 80. FIG. 5 shows an opening 79 which extends through the upper section 74 of the applicator head 60 into an outer compartment 82. Pressurized liquid treatment material is directed to the inner compartment 80 through tubing 62 connected with manually operated valve 85 and then through tubing 86 by a T-connection through opening 88. Tubing 86 is also connected with a manually operated vent valve 88 which would be opened as desired to vent the inner compartment 80 to the atmosphere. Vacuum is drawn on both the inner compartment 80 and outer compartment 82 through tubing 72 connected, as described, to vacuum pump 26. Tubing 72 is connected with a manually operated vacuum valve 90 which in turn is connected by tubing 92 through a T-connection as shown to opening 79 of the outer compartment 82. Tubing 92 is also connected with a manually operated vacuum valve 93 which in turn is connected with tubing 94 connected with opening 83 of the inner compartment of the applicator head 60.

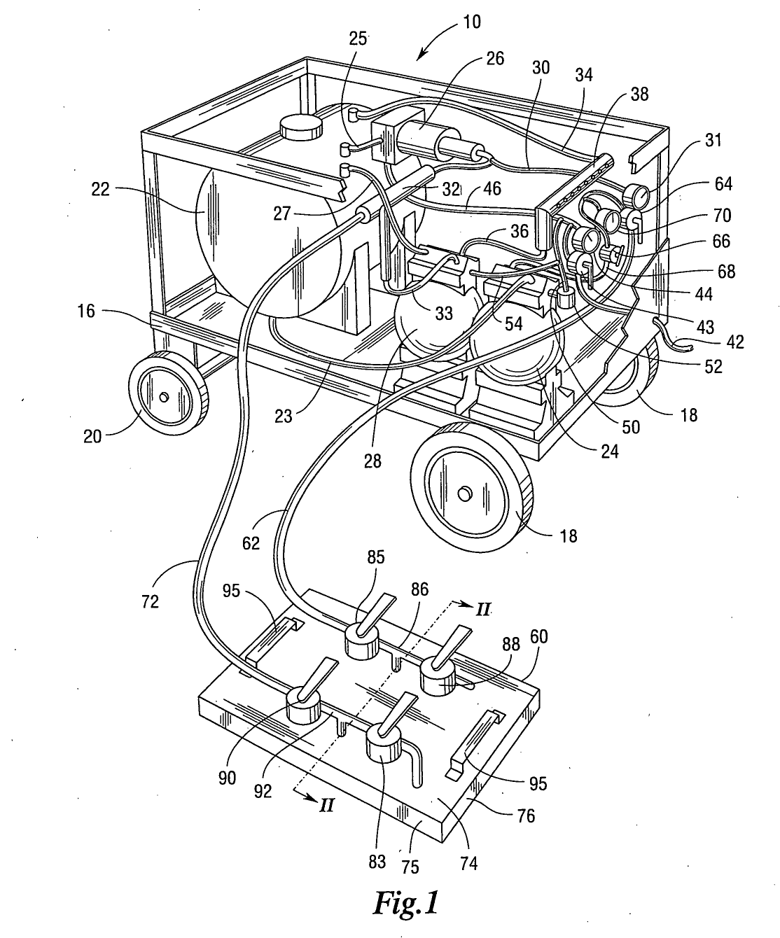

As shown in FIG. 1, handles 95 are fixed to opposite end sections of the upper section 74 of the applicator head 60 for being grasped by a user to position the applicator head 60 on the surface of a structure to be treated such as the structure 12 shown in FIG. 2 and/or to hold the applicator head 60 in place until vacuum attachment is achieved, as will be more fully described hereinafter. FIG. 2 also shows, diagrammatically in part, the interaction of the elements above described with the applicator head 60 in place on structure 12.

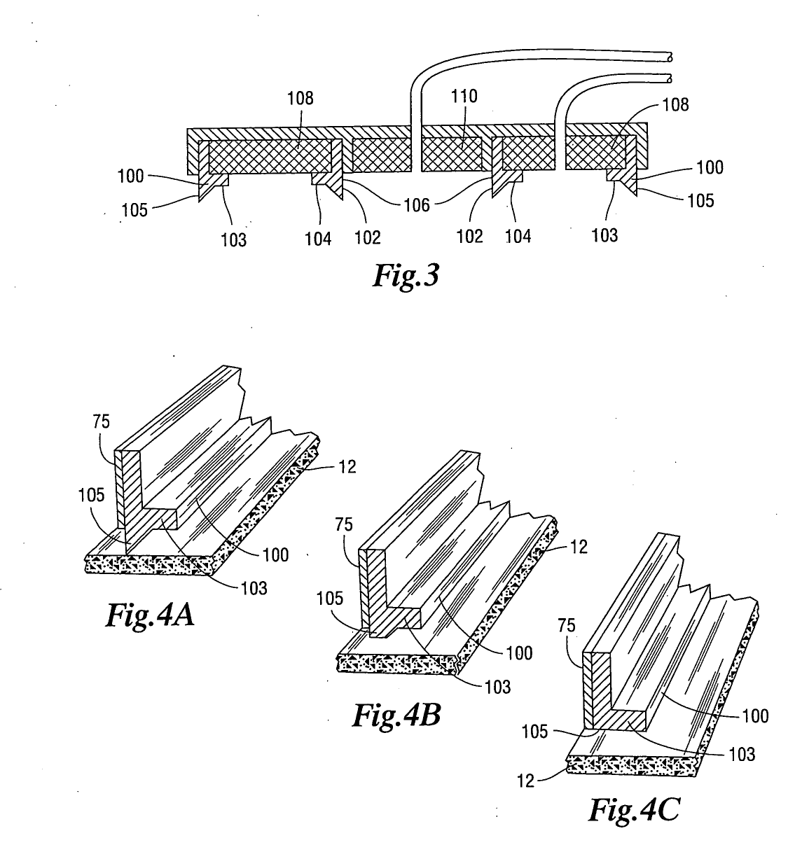

As clearly shown in FIG. 5, the outer compartment 82 of applicator head 60 has a peripheral border formed by the interconnected side walls 75 and end walls 76. Extending downwardly the same dimension from the upper surface 74 of the same applicator head, the inner compartment 80 of applicator head 60 has a peripheral border formed by side walls 96 and 97, each having a depth dimension substantially the same as the depth of dimension of side and end walls 75 and 76. As clearly shown in FIGS. 2-4A, B, C, downwardly extending seals 100 are fixed on the outer peripheral border of the outer compartment 82, that is, on walls 75 and 76. Similarly, a downwardly extending seal 102 is fixed on the peripheral border of the inner compartment 80, that is, on the side walls 96 and 97. As shown in FIGS. 3 and 4A, B, C, the seals 100 and 102 have an inner part 103 and 104, respectively, formed of a resilient low density closed cell foam material, and outer parts 105 and 106, respectively, also formed from the same resilient low density closed cell foam material. The compound seal 100 effects a positive seal between the outer compartment 82 and the surrounding environment, atmosphere or water, when the applicator head 60 is in place and engaging a structure to be treated, and vacuum is drawn on the same outer compartment. Similarly, when the applicator head 60 is in place and engaging a structure to be treated, the composite seal 102 effects a positive seal between the inner compartment 80 and the outer compartment 82. A resilient high density foam sealing blanket 108 is fixed to the inner side upper section 74 of the applicator head 60 and blankets the entirety of outer compartment 82. Similarly, a blanket 110 of high density foam material is fixed on the inner side of upper section 74 of the applicator head 60 and blankets the entirety of the inner compartment 80. The opening 81, 83 and 79 of the inner and outer compartment respectively, extend through the sealing blankets 108 and 110, respectively. The sealing blankets 108 and 110 would serve to squeeze any liquids in the surface of the structure to be treated so that the liquid would tend to flow to the opening 81, 83, and 85, of the inner and outer compartments 80 and 82, respectively. This squeezing action of blanket 110 is significant when the applicator head 60 is placed on a horizontal surface such as a walkway, floor, or such like where the blanket would be compressed under the pressure of the treatment material and would expand toward engaging the surface of the treated structure to thereby urge any excess treatment liquid to the opening 83 and ultimately to the storage tank 22.

In its operation the apparatus 10 of the invention is initially positioned so that the applicator head 60 is engageable with a structure to be treated. The applicator head 60 is held on a surface portion of the structure and the main air valve 44 opened to admit atmospheric air through the pressure regulator 52 to pump 24 which will pump liquid treatment material from the storage tank 22 to the liquid valve 85 which is in the off position. Air will also be directed to the valve 64, it in turn put into the on position to direct air to vacuum pump 26 which will draw a vacuum to valve 90 which will then be opened as will valve 93 to draw a vacuum in the inner compartment 80 and outer compartment 82 of the applicator head 60. The vacuum in the inner and outer compartments 80 and 82, and on the structure engaged by the applicator head 60 will tend to draw any air and liquids on or in the porous structure being treated, such air and liquid flowing through tubing 72 into the liquid/air separator 32 and into the liquid recovery pump 28 which would be operating and from there into the liquid/air separator 38 through the storage tank 22 and into the air vented through the liquid/air separator to the atmosphere and any liquid would be directed into the tank 22. When the preselected and desired vacuum is drawn on the treated structure the applicator head 60 will be drawn onto and positively fixed to the structure and sealed from the structure. Also, the inner compartment 80 will be positively sealed from the outer compartment 82. At that point, the valve 93 will be closed, valve 85 opened to direct pressurized treating liquid to the inner compartment 80 and onto and into the structure to be treated. The outer compartment 82 remains under vacuum to provide a restraining force to keep the applicator head 60 on the treated structure. After the treated structure is impregnated with the treating material, valve 85 is closed shutting the flow of pressurized liquid to inner compartment 80, and valve 85 opened to draw vacuum on the inner compartment 80 and to remove any remaining treating liquid on the surface of the treated structure, the remaining liquid being directed to the storage tank 22 through the liquid recovery pump 28. The vent valve 88 may now be opened to vent the outer compartment 82 to the atmosphere. The main air valve 43 would then be shut, the vacuum pump 26, liquid pump 24, and liquid recovery pump 28 would stop operating, at which point the applicator head 60 would be removed from the treated surface and the operation of the apparatus 10 repeated as desired.

The operation of the apparatus 10 of this invention represents the inventive non-invasive method of the invention in that treating porous structures would apply the steps of engaging in sealed relationship a porous structure an applicator head 60 having defined therein at least one inner second chamber or compartment 80 and at least one outer first chamber or compartment 82 surrounding the inner second chamber, the chambers or compartments being sealed from each other and the structure to be treated, with the chambers or compartments communicating with the structure to be treated; drawing a vacuum on at least the outer first chamber or compartment 82 to secure the applicator head 60 to the structure to be treated; supplying pressurized fluid such as a liquid treatment material to the inner second chamber or compartment 80; and maintaining the vacuum pressure and fluid pressure in the second and first chambers or compartments 80 and 82, respectively, to keep the applicator head 60 in sealed engagement with the structure to be treated.

Typical negative pressure on vacuum to be applied in the treating process would be between about −13 lbs/sq in and −14 lbs/sq in (psi) with the pressure of the treating fluid being between 10 and 15 lbs/sq in (psi) and not at a magnitude which will overcome the vacuum pressure and lift the applicator head 60 from the structure to be treated. The time for applying the pressurized fluid to the first compartment 80 and the structure to be treated would typically be between 15 and 20 seconds after any vacuum drawn on the inner second compartment 80 was ceased, the time for applying the pressurized fluid would depend on the depths of impregnation desired.

The fluid treatment material may be supplied into the inner compartment 80 at pressures greater than between 10 to 15 psi as desired in particular applications and depth of penetration sought in the structure to be treated. The pressure of the treatment material could be between 90 to 120 psi or even higher as explained later herein, and for periods greater than 15 to 20 seconds and typically as high as three minutes. The time of the supplying of the treatment material as the higher pressure could vary for periods longer or shorter, and the treatment material could be supplied at pressures less or more than those stated and anywhere between the stated ranges of pressures as particular applications and depths or penetration would dictate.

The vacuum serves two functions, holding down the applicator head and modifying the movement of treatment material in the substrate of the structure to be treated. These functions lead to several considerations in choosing an appropriate vacuum level.

The primary function of the vacuum is to hold down the pressure area to permit the injection of the treatment material. In this function, the highest possible vacuum is generally desirable, however, under some conditions, a lower vacuum may be preferable. Vacuum is limited to no more than the atmospheric pressure, which would be approx. −15 psi. That would be an ideal pressure, but with expected leakage and reasonable quality pumps, a pressure within 1-2 psi of atmospheric is probably the highest practically obtainable. This would give pressure of −13 to −14 psi at sea level and −10 to −11 in high altitudes like Vail, Colo., for example.

The vacuum causes a very high force across the substrate of the structure being treated so the substrate must be able to handle the force applied by the vacuum. For example, in a 30 in.×30 in. area with a vacuum of −15 psi, the total force across the area would be 13,500 lbs. Weakened substrates such as delaminated concrete, concrete with extensive corrosion or ASR damage, delicate or thin substrates such as veneers or stuccos may not be able to withstand high forces so the total force must be evaluated and a vacuum within range chosen. Vacuum for such thin substrates may range anywhere from just above 0 to −15 psi depending on the thickness of the substrate and conditions.

The vacuum's second function, of modifying the movement of materials is a complex interaction of the vacuum and pressure areas and the substrate. The simplest interaction is that the vacuum being initially applied to both compartments of the applicator head, removes liquids, gasses and vapors from the substrate. The depth and area affected is dependent on many factors including the condition, permeability, saturation and chemical composition of the substrate. A more complex interaction is that a vacuum gradient generated in the substrate can modify the movement of the injected material.

A final consideration is that the vacuum can cause the injected treatment material to boil if exposed to the vacuum. This is generally not a consideration, but under some foreseeable operating modes, it could be a concern.

One of the main advantages of this invention over any other, is that it permits a surface of a structure to be treated, that is substrate, to be exposed to a high pressure fluid (liquid, gas, vapor) without any holes or attachment to the substrate. This permits the fluid treatment material to be injected (penetrate) into the substrate.

There are two different fluid pressures involved in this invention, the pressure at the surface of the substrate and the pressure at the fluid pump. These will differ based on flow rates, hose sizes, elevation differences, etc. The most relevant pressure is the fluid pressure at the surface of the substrate. In a closed chamber with little flow (static), such as when the hood is fully in contact with the substrate, pressures in all parts of the inner compartment, or pipes with multiple openings into the inner compartment, do not change this basic concept in hydraulics. Pressure differences are zero in a horizontal compartment and vary by ½ psi per foot in a vertical compartment. Over sizes of applicator heads likely to be used, perhaps 10 feet or less, this difference in the worse case is only 5 psi.

The fluid pressure at the surface of the substrate and structures to be treated has no real upper limit and higher fluid pressure will increase the rate and depth of penetration of the fluid. There are of course practical considerations which set upper operating limits in a specific application. Fluid pressure regulation should be performed at a point in the system where the pressure is representative of the pressure at the surface. This could be done at the pump in systems where the hose length is relatively short and the elevation is the same. It should be done at the applicator head in systems with long hose lengths or significant differences in elevation.

The first is similar to the vacuum limit, the substrate must be able to withstand the static force created by the pressure. The second is the mechanical balance between the pressure and vacuum compartments. The total force in the vacuum outer compartment/s must be greater than the total force in the pressure inner compartment/s or the applicator head will come loose of the substrate. The ratio of the compartment sizes sets this limit. Several factors are considered when choosing this ratio. Higher pressures give faster penetration, but smaller coverage areas. In very low permeability substrates, an injection pressure of 100 psi or higher may be desirable but would require chamber ratios of almost 10:1 (vacuum area: pressure area) so a relatively small application area for each time the applicator head is moved. High permeability substrates such as stucco, gypsum, etc can use injection pressures as low as 1-2 psi successfully or even flooding the chamber without a static pressure. This permits compartment ratios of 1:10 or more permitting very large application areas each time the applicator head is moved. So any pressure between 0 and hundreds or thousands of psi can used.

A third consideration is the substrate. If the rate of penetration is too high, fluid channels could be cut in the substrate rather than having a uniform diffusion into the substrate. If the substrate is delaminated, fluid pressure in an area of delamination could further delaminate the section or cause separation. These would be reasons to reduce the application pressure.

Once the desired operating pressure for the fluid at the surface of the substrate is known, then determining the fluid pump pressure is straightforward. The parameters that affect this are head, flow rate, and restrictions. Head is the height of the applicator head above the pump. Since water based fluids have a head pressure of approx. 0.5 psi per foot in elevation, the pump must have an output pressure equal to the head pressure plus the surface pressure. For example, the applicator head is 100 feet above the pump and fluid must reach the surface at 60 psi. Then the output pressure must be at least 100 psi.

The second consideration is pressure loss due to flow restrictions such as line size, bends, valves, filters, etc. For efficient operation, the initial flow rate needs to be high so the chamber can be filled quickly. Once the chamber is filled and the surface has reached the desired injection pressure, the flow rate will be reduced to just the seal leakage and the treatment material entering the substrate. Normal hydraulic engineering can be used to determine flow losses.

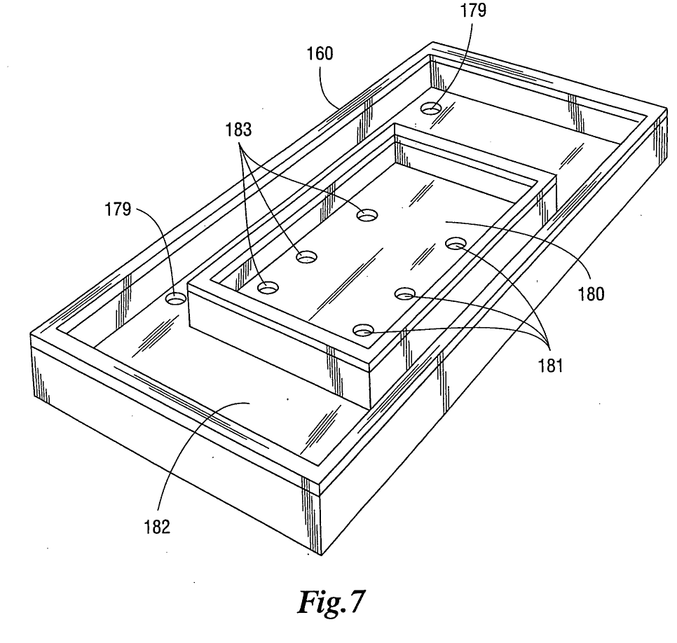

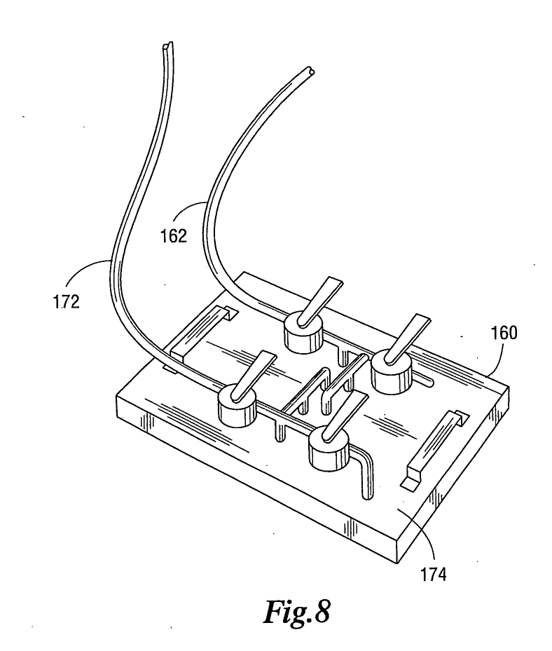

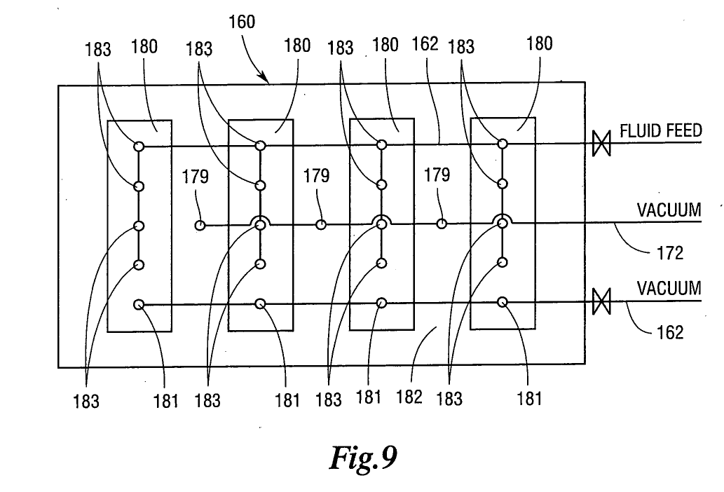

Along with varying the pressure of the treating material and the time period of treatment, the applicator head 60 could be adapted to accommodate the higher pressures. As shown in FIGS. 7 and 8 the applicator head 160 of similar overall shape as applicator head 60, includes inner compartments 180 with a series of spaced openings 183 extending through the upper section 174 of the applicator head 160 into the inner compartment 180. A series of inner compartments 180 as shown in FIG. 9 with a single outer compartment 182 could be provided. Surrounding the inner compartments 180 would be a continuous uninterrupted outer compartment 182, also shown in FIG. 9, with spaced opening 179 extending from the upper surface of applicator head 160 into the outer compartment 182. With the single inner compartment 180 the outer compartment 182 would surround it much like the arrangement in applicator head 60. As shown in FIG. 7, the inner compartment 180 of both FIGS. 7 and 9 are provided with spaced openings 181 for venting the same inner compartments 180 to the atmosphere as in applicator head 60. Also, excess treatment liquid would be discharged from the inner compartments 180 through the openings 183. Pressurized treatment material would be directed to and vacuum drawn on the inner compartment 180 through tubing 162, shown schematically in FIG. 9, connected to the opening 181. Vacuum would be drawn in the outer compartment 182 through tubing 172 connected to openings 179. The tubing 162 and 172 would be connected to the components and source of treatment material, shown schematically in FIG. 9, and valving typically as that associated with applicator head 60. The operation of applicator heads 160 would be basically the same as the operation of applicator head 60 as describe herein. As shown, the inner compartments 180 and outer compartments 181 have side and end walls forming them, which side and end walls are provided with seals typically like the seals shaped and arranged on the side and end walls forming the compartments of applicator head 60. Sealing blankets could also be arranged on the upper surface 174 of the applicator head 160 to function in the same manner as the sealing blankets 108 and 110 of the applicator head 60.

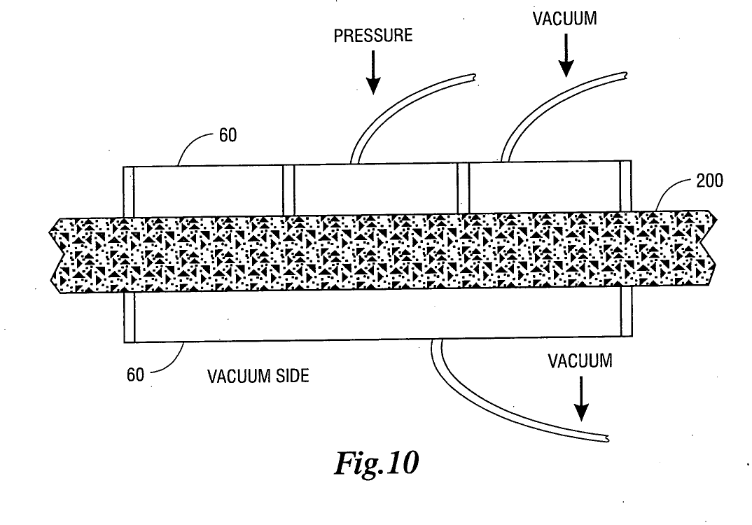

It is also to be noted that a side-by-side series of interconnected applicator heads 60 could be used on large extending surfaces such as airport runways, roads, and the like. Where slab-like structures such as an elevated platform 200 shown in FIG. 10 is to be treated, an applicator head 60 would be secured to the upper surface of the platform 200 and an applicator head 60 secured to the lower surface. Both applicator heads 60 would be interconnected to the source of the treating material, vacuum drawing, sources, and components in essentially the same manner as the interconnections described herein, and operated in essentially the same manner as the applicator head 60 of FIGS. 1-6.

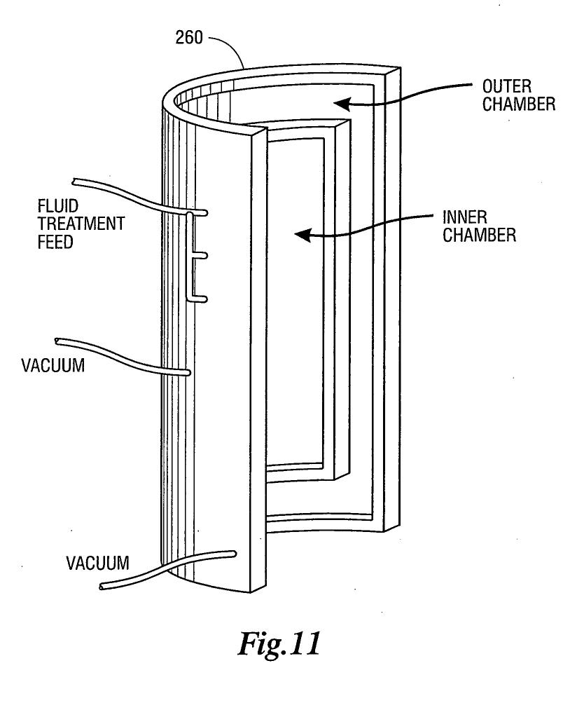

FIG. 11 shows diagrammatically and schematically a semi-cylindrical applicator head 260 which functions basically the same as applicator head 60. The applicator head 260 would be used with a complimentary applicator head to surround a cylindrical structure such as a support column. Although not shown, the applicator head 260 would be provided with tubing and openings in the inner and outer chambers for directing fluid treatment material and draw vacuum.

In using the apparatus 10 of the invention it might also be necessary to fill any cracks in the surface area of the structure to be treated to close any possible channels open to the second compartment 82 which channels would prevent the desired vacuum to be drawn on the second compartment and prevent the development of the holding force for securing the applicator head 60 to the treated structure.

Several applications of this invention have resulted in positive treatment results. In one application the applicator head 60 was formed of ⅛ inch thick steel plate having overall dimensions of 18×40 inches. The inner compartment 80 had dimensions of 6×34 inches. Both compartments were provided with flexible foam rubber seals. The inner compartment had an area of 204 sq. inches and the outer compartment had an area of 516 sq. inches. Valves were secured to two one inch openings to the inner compartment 80 and to a one inch opening into the outer compartment 82. As earlier described liquid pumps and a vacuum venturi pump were operatively connected to the compartments. The applicator head 60 was positioned on a flat vertical reinforced concrete surface of a pile cap supporting a wharf deck. A vacuum of minus 14 psi was generated and drawn on the compartments. The applicator head 60 was held securely on the vertical surface. The vacuum was initially applied for about one minute removing the water and air entrained in the concrete. The vacuum was shut off from the inner compartment 80 and a liquid corrosion inhibitor was injected under a pressure of about 20 psi and held for about three minutes. During this time several gallons of inhibitor was injected into the concrete. The liquid valve to the inner compartment was shut off and the vacuum valve opened resulting in the excess inhibitor flowing back to the storage tank. The system was shut down and the applicator head removed. Prior to the injection of the inhibitor which was the TPS II corrosion inhibitor of Surtreat International, the corrosion rate of the reinforcement members in the pile cap at a depth of 5 inches was measured at 500 um/Yr. using a gavalanostic polarization device called a Galvapuls. After the treatment as described and twenty-four hours later the corrosion rate was measured at 20 um/Yr. demonstrating that the vacuum pressure injection of the inhibitor was to a depth of five inches in about three minutes.

In another application of the present invention, a rectangular applicator head 60 was used formed of a 1/16 inch thick steel plate having outer dimensions of 24×36×½ inches. The outer perimeter or periphery of the applicator head 60 was provided with a 2×1 inch flexible closed cell foam rubber seal. The inner compartment 80 had dimensions of 12×24 inches with the same dimensions of flexible closed cell foam rubber seals provided on its periphery. The outer compartment had an area of 528 sq. inches and the inner compartment an area of 336 sq. inches. Openings of one inch in diameter were formed to communicate with the inner and outer compartments. A venturi vacuum pump and liquid pump communicated with the liquid storage tank and the compartments, as described earlier. The applicator head was placed on a flat reinforced concrete surface of a condominium building balcony. Compressed air at 100 psi and at 30 cfm was passed through the venturi vacuum pump and generated a vacuum of minus 22 mmHg. This negative pressure securely fixed the applicator head to the surface of the balcony. The vacuum was held for about one minute to evacuate entrained air from the concrete structure. A liquid corrosion inhibitor made by Surtreat International known as TPII was directed at 22 psi to the inner compartment by a liquid pressure pump and held for about three minutes. The liquid pressure was released and the inner chamber cycled to vacuum to remove excess inhibitor to the storage tank. The system was shut down and the applicator head removed. Prior to the injection of the corrosion inhibitor the corrosion rate of the reinforcing bar at a depth of two inches was measured at above 500 um/Yr. using a gavalanostic polarization device called Galvapuls. Thirty days after inhibitor injection the corrosion rate of the same rebar was measured below 20 um/Yr. Fifteen days after the inhibitor injection the compressive strength of the structure was re-measured at an increase of 390 psi for a total compressive strength of 6560 psi. In yet another application of the apparatus and method of the invention, a rectangular enclosure consisting of 040 plastic PVC having dimensions of 2×4×1 inches was used. The outer perimeter or periphery of this applicator head was provided with a ⅓×⅓ inches of flexible closed cell foam rubber sealing material. The periphery of the inner compartment had dimension of 1×2½ inches and was provided with the same ⅓×⅓ inches of flexible closed cell foam rubber seal material. Openings of ¼ in. diameter were made to the inner and outer compartments. A valve was attached to the outer compartment and connected with a vacuum generating device and a liquid separating device. The inner compartment communicated with a storage tank through a liquid pressure pump. The applicator head was placed on the top of a 2×4×½ inches sand cast brick approximately one hundred years old. The vacuum device generated a vacuum of minus 14 mmHg which was sufficient to hold the applicator head in place on the sand cast brick. The vacuum was held on both compartments for about one minute to evacuate entrained air from the sand cast brick. A liquid corrosion inhibitor of Surtreat International known as TPS II was applied at a positive pressure of 8 psi by a liquid pressure pump for about five minutes. The liquid zone pressure was released and the excess liquid in the inner compartment allowed to flow back to the storage tank. The system was shut off and the applicator head removed. Prior to the injection of the corrosion inhibitor the sand cast brick was severely damaged and powdered on handling. This brick was delaminating into five separate layers on the longitudinal axis. One day after injecting the corrosion inhibitor the strength and hardness of the sand cast brick was sealed eliminating the delimitation creating a solid structure.

Various other examples of the application of the apparatus and method of the invention may be provided with the positive results to the structures typical of what has been indicated hereinabove.

Various modifications of the invention are possible. The applicator head 60 may be formed in any configuration for use with varying shapes of porous structures. For example, the applicator head 60 could be formed as a cylindrical section 260 to fit onto a cylindrical structure. The seals could be shaped and formed to engage variously shaped structures as well. The apparatus 10 could be adjusted for injecting gaseous or vaporized treatment materials into treated structures. For example, steam might be injected to thaw frozen structures. The applications of this apparatus and method of this invention are beyond strengthening structural bodies. The invention could be used in injecting insecticides through structures such as concrete patios, walkways, and floors, or wooden structures to kill termites. The invention could be used in injecting chemicals into plaster or wall board walls and ceilings to kill molds and such like. Various other modifications and advantages of the apparatus of this invention for treating porous structures and the method of treating porous structures of this invention should be clearly understood by those skilled in this art.

It should now be clearly understood and apparent that the apparatus and method of this invention is effectively and efficiently useable in treating porous structures such as those formed from masonry, concrete, brick stone, marble, and/or wood including those structures having reinforcement members or other members embedded therein, whether those structures are horizontally oriented, including ceilings, or upright oriented such as walls, pilings, or such like, and whether the structures are in the atmosphere or under water.

While I have shown and described a present preferred embodiment of this invention and method of practicing the invention, it is to be distinctly understood that the invention is not limited thereto, but may be otherwise embodied and practiced within the scope of the following claims.

I claim:

1. The non-invasive method of treating porous structures, comprising the steps of:
engaging in sealed relationship to and on the surface of a porous structure an applicator head having defined therein at least one outer first chamber and at least one inner second chamber within said first chamber, said chambers sealed from each other and the structure to be treated with said chamber communicating with the structure to be treated;
drawing a vacuum on at least said outer first chamber to secure said applicator head to the structure to be treated;
supplying pressurized fluid treatment material to said inner second chamber and onto the surface of the structure to be treated;
said supplying being at a pressure sufficient for said fluid treatment material to impregnate the structure to be treated from the surface thereof into its confines; and
maintaining the vacuum pressure and fluid pressure in said first and second chambers, respectively, to keep the said applicator head in sealed engagement with the structure to be treated.

2. The non-invasive method of treating as set forth in claim 1 wherein said step of drawing a vacuum is on each of said first and second chambers; and including the step of withdrawing the vacuum from said second chamber prior to supplying pressurized fluid treatment material to said second chamber.

3. The non-invasive method of treating as set forth in claim 1 including the steps of discontinuing the function of said drawing the vacuum on said first chamber and said supplying the fluid treatment material to the second chamber when the desired impregnation of the structure to be treated is achieved.

4. The non-invasive method of treating as set forth in claim 1 including the step of removing substantially all fluids from the surface area of at least the section of the structure to be treated and substantially all fluids within the section of the same structure to be treated, prior to said supplying of the fluid treatment material.

5. The non-invasive method of treating as set forth in claim 1 including the step of breaking apart any material coating on the surface area of at least the section of the structure to be treated prior to said step of supplying pressurized fluid treatment material to impregnate the structure to be treated.

6. The non-invasive method of treating as set forth in claim 1 including the step of regulating the vacuum on said first chamber to maintain a desired predetermined vacuum therein during said step of supplying pressurized fluid preservative treatment material.

7. The non-invasive method of treating as set forth in claim 1 wherein said engaging of said applicator head is onto at least a section of a porous structure to be treated at an oblique angle to a horizontal plane.

8. The non-invasive method of treating as set forth in claim 1 wherein said engaging of said applicator head is onto at least a downwardly facing section of a porous structure to be treated; and wherein said supplying of pressurized fluid is upwardly against gravity.

9. The non-invasive method of treating as set forth in claim 1 wherein said supplying step is of pressurized liquid preservative material.

10. The non-invasive method of treating as set forth in claim 1 wherein said steps are applied on a structure under water.

11. The non-invasive method of treating as set forth in claim 1 wherein said drawing a vacuum is at a vacuum of between about −11 and −13 psi.

12. The non-invasive method of treating as set forth in claim 1 wherein said supplying pressurized fluid treatment material is between pressures of about 10 and 15 psi.

13. The non-invasive method of treating porous structures, comprising the steps of:
forming a first enclosure on the surface of a porous structure to be treated;
arranging said first enclosure on the surface of the porous structure to be treated in sealed relationship therewith;
defining a second enclosure on the porous structure within the confines of said first enclosure;
fixing said second enclosure on the surface of the porous structure;
drawing a vacuum on at least said first enclosure;
supplying a pressurized fluid treatment material to said second enclosure and onto the surface of the porous structure until at least a portion of the porous structure is internally impregnated at least in part with the fluid treatment material;
said drawing being at a vacuum sufficient to keep said first enclosure in fixed sealed relationship to the porous structure during said supplying of the pressurized fluid material; and
maintaining said drawing of a vacuum on said first enclosure while supplying the fluid treatment material to said second enclosure.

14. The non-invasive method of treating as set forth in claim 13 wherein the steps of drawing a vacuum is on each of said first and second enclosures; and including the step of withdrawing the vacuum from said second enclosure prior to supplying pressurized fluid treatment material to said second enclosure.

15. The non-invasive method of treating as set forth in claim 13 including the steps of discontinuing the functions of said drawing the vacuum on said first enclosure and said supplying the fluid treatment material to said second enclosure once the desired impregnation of the structure to be treated is achieved.

16. The non-invasive method of treating as set forth in claim 13 including the step of removing substantially all fluids from the surface area of at least the section of the structure to be treated and substantially all fluids within confines of the section of the structure to be treated prior to said supplying of the pressurized fluid treatment material.

17. The non-invasive method of treating as set forth in claim 13 including the step of regulating the vacuum in said first enclosure to maintain a desired predetermined vacuum therein during said step of supplying pressured treatment material, for securing said first enclosure to the structure to be treated.

18. The non-invasive method of treating as set forth in claim 13 wherein the porous structure to be treated is at an oblique angle to a horizontal plane, including, but not limited to, being vertically oriented.

19. The non-invasive method of treating as set forth in claim 13 wherein the porous structure to be treated is facing downwardly; and wherein said supplying of pressurized fluid is upwardly against gravity.

20. The non-invasive method of treating as set forth in claim 13 wherein said supplying step is of pressurized liquid preservative material.

21. The non-invasive method of treating as set forth in claim 13 wherein said steps are applied on a structure under water.

22. A non-invasive method of treating a porous material, comprising: attaching an injection hood to a porous material, wherein the injection hood comprises:
a hood structure having a top plate and at least one side wall extending out of a plane of the top plate and forming a first cavity;
a plurality of injection ports extending through the top plate of the hood structure and positioned in the first cavity;
at least one vacuum hole-extending through the top plate of the hood structure and positioned in the first cavity;
a fluid transport conduit coupled to the plurality of injection ports in the second cavity;
a first seal coupled to the at least one side wall and configured to seal the first cavity to a surface of a porous material to be injected with a protective material;
passing a protective material through a pump;
injecting the protective material through the plurality of injection ports and into the porous material.

23. The non-invasive method of treating a porous material of claim 22, wherein attaching the injection hood to a porous material comprises using a mechanical connector to attach the injection hood to a porous material.

24. The non-invasive method of treating a porous material of claim 22, wherein attaching an injection hood to a porous material comprises attaching an injection hood having a sealing rib extending from the hood structure of the top plate and forming a second cavity in the hood structure of the top plate and forming a second cavity in the hood structure and within the first cavity and having a second seal coupled to the sealing rib forming the second cavity and configured to seal the second cavity to the surface of the porous material to be injected with a protective material.

25. The non-invasive method of treating a porous material of claim 22, wherein attaching an injection hood to a porous material comprises placing the injection hood in contact with the porous material such that the first and second seals contact the porous material and forming a vacuum in the first cavity.

26. The non-invasive method of treating a porous material of claim 22, wherein injecting the protective material through the plurality of injection ports and into the porous material comprises injecting the protective material into the second cavity.

27. The non-invasive method of treating a porous material of claim 22, wherein injecting the protective material through the plurality of injection ports and into the porous material comprises injecting the protective material at a pressure of between about 90 psi and 120 psi.

28. The non-invasive method of treating a porous material of claim 22, wherein injecting the protective material through the plurality of injection ports and into the porous material comprises injecting a protective material containing a dye usable to visually track progression of the protective material through the porous material.

29. The non-invasive method of treating a porous material of claim 22, further comprising withdrawing excess protective material from an outer surface of the porous material with a vacuum and depositing the material in a storage tank.

30. The non-invasive method of treating a porous material of claim 28, further comprises passing the protective material through a carbon filter before being deposited into a storage tank.

31. The non-invasive method of treating a porous material of claim 22, wherein injecting the protective material through the plurality of injection ports and into the porous material comprises injecting a protective material that is capable of being injected into a porous material at a pressure range of between about 90 psi and 120 psi without producing foam in an amount that impedes uptake of the protective material into the porous material and operation of the injection hood.

32. The non-invasive method of treating a porous material of claim 22, wherein injecting the protective material through the plurality of injection ports and into the porous material comprises injecting a protective material having a potassium base without a surfactant.

33. A porous structure treatment system applicator head, comprising:
a top structure and side wall means for defining an inner second chamber;
inner wall means for defining an outer first chamber surrounding said second chamber;
fluid treatment material means defining at least one opening into said second chamber for supplying pressurized fluid into said second chamber;
first vacuum drawing means defining at least one opening into said first chamber for drawing a vacuum in said first chamber; and
said top structure, inner wall means, fluid treatment means, and first vacuum drawing means being constructed and arranged such that the applicator head will engage a porous structure to be treated.

34. The porous structure treatment applicator head as set forth in claim 33, wherein said fluid treatment material means defines a plurality of openings into said second chamber for supplying pressurized fluid said first chamber.

35. The porous structure treatment applicator head as set forth in claim 33, including second vacuum drawing means defining at least one opening into said second chamber for drawing a vacuum in said second chamber.

36. The porous structure treatment applicator head as set forth in claim 33, including first sealing means communicating with the border of said first chamber for effecting a seal between said first chamber and a porous structure to be treated and between said first chamber and said second chamber when the applicator head engages a porous structure to be treated; and
including second sealing means communicating with the border of said second chamber for effecting a seal between said second chamber and a porous structure to be treated.

37. The porous structure treatment applicator head as set forth in claim 33, wherein said first and second chambers are shaped to conform to the exterior shape of the structure to be treated and with peripheral borders snugly engageable with the surface of the porous structure to be treated.

38. The porous structure treatment applicator head as set forth in claim 33, wherein said top structure and side wall means forms a plurality of second chambers; and wherein said fluid treatment means defines at least one opening into each of said second chambers.

39. The porous structure treatment applicator head as set forth in claim 38, wherein said fluid treatment means defines a plurality of openings into at least one of said second chambers.

40. The porous structure treatment applicator head as set forth in claim 38, wherein said fluid treatment means defines a plurality of openings into each of said second chambers.

41. The porous structure treatment applicator head as set forth in claim 38, wherein said second chamber is a single continuous chamber surrounding each of said first chambers.

42. The porous structure treatment applicator head as set forth in claim 33, includes at least one additional applicator head means as defined in claim 33, constructed and arranged such that it will or they will engage a porous structure to be treated.

43. The porous structure treatment applicator head as set forth in claim 42, wherein said applicator head as defined in claim 33, and said applicator head means are constructed and arranged such that said applicator head will engage the upper portions of a porous structure to be treated and a said applicator head means will engage the lower portion of the same porous structure.
